(19) United States
(12) Patent Application Publication
(10) Pub. No.: US 2012/0145991 A1
(43) Pub. Date: Jun. 14, 2012

(54) HIGH-QUALITY NON-POLAR/SEMI-POLAR SEMICONDUCTOR ELEMENT ON TILT SUBSTRATE AND FABRICATION METHOD THEREOF

(75) Inventors: Ok Hyun Nam, Seoul (KR); Jong Jin Jang, Incheon city (KR)

(73) Assignee: SEOUL OPTO DEVICE CO., LTD., Ansan-si (KR)

(21) Appl. No.: 13/392,059

(22) PCT Filed: Aug. 27, 2010
(86) PCT No.: PCT/KR10/05762

§ 371 Date: Feb. 23, 2012

(30) Foreign Application Priority Data
Aug. 27, 2009 (KR) 10-2009-0080057

(51) Int. Cl. H01L 33/06; H01L 33/14

(52) U.S. Cl. 257/13; 438/47; 257/E33.008; 257/E33.025

(57) ABSTRACT

Provided are a high-quality non-polar/semi-polar semiconductor device and a manufacturing method thereof. A template layer is formed on a corresponding off-axis of the sapphire crystal plane tilted in a predetermined direction to reduce the defect density of the semiconductor device and improve the internal quantum efficiency and light extraction efficiency thereof. In the method for manufacturing the semiconductor device, a template layer and a semiconductor device structure are formed on a sapphire substrate having a crystal plane for growing a non-polar or semi-polar nitride semiconductor layer. The crystal plane of the sapphire substrate is tilted in a predetermined direction, and the template layer includes a nitride semiconductor layer and a GaN layer on the tilted sapphire substrate.

### CROSS-REFERENCE RELATED APPLICATIONS

This application is the National Stage Entry of International Application No. PCT/KR2010/005762, filed on Aug. 27, 2010, which claims priority from and the benefit of Korean Patent Application No. 10-2009-0080057, filed on Aug. 27, 2009, both of which are herein incorporated by reference for all purposes as if fully set forth herein.

### BACKGROUND

1. Technical Field

The present invention relates to a semiconductor optical device and a manufacturing method thereof, and more particularly, to a high-quality non-polar/semi-polar semiconductor device and a manufacturing method thereof. In the high-quality non-polar/semi-polar semiconductor device, a non-polar/semi-polar nitride semiconductor crystal is formed on a sapphire crystal plane, which enables the growth of a non-polar/semi-polar nitride semiconductor layer, in order that a piezoelectric effect generated in a polar nitride semiconductor layer may not occur in a nitride semiconductor layer. In addition, a template layer is formed on a corresponding off-axis of the sapphire crystal plane tilted in a predetermined direction to reduce the defect density of the semiconductor device and improve the internal quantum efficiency and light extraction efficiency thereof.

2. Discussion of the Background

Since group III-V nitride semiconductors (also simply called “nitride semiconductors”), such as GaN, have excellent physical and chemical properties, they have recently been recognized as the essential material for semiconductor optical devices, such as a light emitting diode (LED), a laser diode (LD), and a solar cell. Group III-V nitride semiconductors are typically composed of a semiconductor material having an empirical formula of InₓAl_{y}Ga_{1-x-y}N (0≦x≦1, 0≦y≦1, 0≦x+y≦1). Such nitride semiconductor optical devices are employed as light sources for a variety of products, such as a keypad of a mobile phone, an electronic display board, and a lighting device.

In particular, as digital products using LEDs or LDs have evolved, there is an increasing demand for nitride semiconductor optical devices having higher brightness and higher reliability. For example, a side view LED used as a backlight of a mobile phone is required to be brighter and thinner as the mobile phone tends to be slimmer. However, if a nitride semiconductor, such as polar GaN, is grown on a sapphire substrate using a C-plane (e.g., (0001) plane) as a sapphire crystal plane, the internal quantum efficiency may be reduced by a piezoelectric effect caused by the formation of a polarization field.

Accordingly, it is necessary to form a non-polar/semi-polar nitride semiconductor on a sapphire substrate. However, crystal defects, such as a line defect and an area defect, may be caused by a lattice mismatch between sapphire, which is suitable for the formation of a template layer using non-polar/semi-polar GaN or the like, and a non-polar/semi-polar nitride semiconductor template layer, which is formed on the sapphire, and a difference in coefficient of thermal expansion between constituent elements. Such crystal defects have a bad influence on the reliability of an optical device, for example, a resistance to electrostatic discharge (ESD), and are also the cause of current leakage within the optical device. As a result, the quantum efficiency of the optical device may be reduced, leading to the performance degradation of the optical device.

A variety of efforts have been made to reduce a crystal defect of a nitride semiconductor layer. One of these efforts is the use of a selective epitaxial growth. However, these efforts require high costs and complicated processes, such as SiO₂ mask deposition. In addition, a crystal defect may be reduced by forming a low-temperature buffer layer on a sapphire substrate and then forming GaN thereon. However, this is not enough to solve a crystal defect problem of an optical device. Therefore, it is necessary to solve a problem that degrades the brightness and reliability of an optical device due to a crystal defect.

### SUMMARY

The present invention is directed to solving the above-mentioned problem. An object of the present invention is to provide a high-quality non-polar/semi-polar semiconductor device and a manufacturing method thereof. In the high-quality non-polar/semi-polar semiconductor device, a nitride semiconductor crystal is formed on a sapphire crystal plane, which enables the growth of a non-polar/semi-polar nitride semiconductor layer, in order to eliminate a piezoelectric effect generated in a polar GaN nitride semiconductor. In addition, a template layer is formed on a corresponding off-axis of the sapphire crystal plane tilted in a predetermined direction. Therefore, a surface profile may be improved and a defect of the template layer may be reduced, improving crystal quality.

Summarizing the present invention, a method for manufacturing a semiconductor device, in which a template layer and a semiconductor device structure are formed on a sapphire substrate having a crystal plane for growing a non-polar or semi-polar nitride semiconductor layer, includes: preparing the sapphire substrate, the crystal plane of which is tilted in a predetermined direction; and forming the template layer including a nitride semiconductor layer and a GaN layer on the tilted sapphire substrate.

A semiconductor device may be manufactured by the manufacturing method. The crystal plane of the sapphire substrate may include an A-plane, an M-plane, and an R-plane.

The crystal plane of the sapphire substrate may be an A-plane, an M-plane, or an R-plane, and may be tilted in an A-direction, an M-direction, an R-direction, or a C-direction.

The crystal plane of the sapphire substrate may be tilted in a range of 0 to 10 degrees with respect to a horizontal plane.

The nitride semiconductor layer may include an InₓAl_{y}Ga_{1-x-y}N layer (0≦x≦1, 0≦y≦1, 0≦x+y≦1).

The semiconductor device may include a light emitting diode (LED) having an active layer between an n-type nitride semiconductor layer and a p-type nitride semiconductor layer. In addition, the semiconductor device may include an optical device including a light emitting diode, a laser diode, a photo detector, or a solar cell, or may include an electronic device including a transistor.

According to the semiconductor device and the manufacturing method thereof set forth above, the template layer is formed on the corresponding off-axis of the sapphire crystal plane, which enables the growth of the non-polar/semi-polar nitride semiconductor layer and is tilted in a predetermined direction, and the nitride semiconductor optical device is formed on the template layer. Therefore, the nitride semiconductor layer may have a low crystal defect density, improving the reliability and performance (e.g., brightness) of the semiconductor device.

### BRIEF DESCRIPTION OF THE DRAWINGS

FIG. 1 illustrates a sapphire crystal structure for explaining a crystal plane of a sapphire substrate.

FIG. 2 illustrates a semi-polar GaN crystal structure for explaining a semi-polar nitride semiconductor layer.

FIG. 3 illustrates a tilt direction of a sapphire substrate according to an embodiment of the present invention.

FIG. 4 is a cross-sectional view for explaining a structure of a semiconductor optical device according to an embodiment of the present invention.

FIG. 5 is an optical microscope (OM) image photograph for comparing crystal states of a surface of an undoped GaN layer between a semiconductor optical device structure of the related art and a semiconductor optical device structure of the present invention.

FIG. 6 is a view for explaining an X-ray diffraction (XRD) peak of an undoped GaN layer in the structure of the related art.

FIG. 7 is a view for explaining an XRD peak of an undoped GaN layer in the structure of the present invention.

FIG. 8 is a graph for comparing photoluminescence (PL) intensities between the semiconductor optical device structure of the related art and the semiconductor optical device structure of the present invention.

### DETAILED DESCRIPTION OF EXEMPLARY EMBODIMENTS

Exemplary embodiments of the present invention will be described below in detail with reference to the accompanying drawings. The invention, however, should not be construed as being limited to the embodiments set forth herein. Throughout the drawings and description, like reference numerals will be used to refer to like elements.

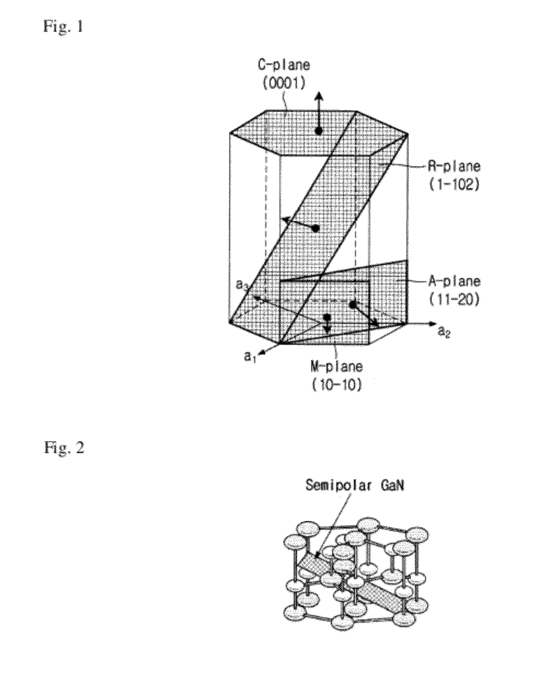

FIG. 1 illustrates a sapphire crystal structure for explaining a crystal plane of a sapphire substrate.

In general, if a nitride semiconductor, such as polar GaN, is grown on a sapphire substrate using a C-plane (e.g., (0001) plane) as a sapphire crystal plane, as illustrated in FIG. 1, the internal quantum efficiency may be reduced by a piezoelectric effect caused by the formation of a polarization field.

In an embodiment of the present invention, a nitride semiconductor optical device structure, such as an LED, an LD, or a solar cell, is formed on a sapphire substrate, and an A-plane (e.g., (11-20) plane), an M-plane (e.g., (10-10) plane), or an R-plane (e.g., (1-102) plane) in FIG. 1 is used as a crystal plane of the sapphire substrate, so that a non-polar or semi-polar nitride semiconductor layer can be grown thereon. If necessary, the C-plane may be used as the crystal plane of the sapphire substrate, and a non-polar or semi-polar nitride semiconductor layer may be formed thereon.

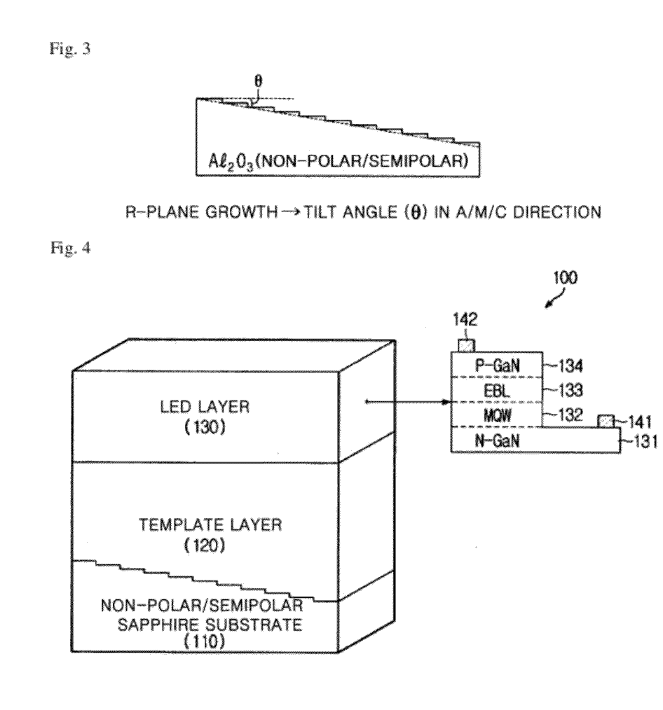

In particular, a substrate used in an embodiment of the present invention is a sapphire (Al₂O₃) substrate, a crystal plane of which is tilted in a predetermined direction as illustrated in FIG. 3. For example, in a case where the crystal plane of the sapphire substrate is the R-plane, the sapphire substrate may be manufactured such that the crystal thereof is grown to be tilted in an A-direction, an M-direction, or a C-direction. Likewise, in a case where the crystal plane of the sapphire substrate is the A-plane, a tilt direction may be an R-direction, an M-direction, or a C-direction. In a case where the crystal plane of the sapphire substrate is the M-plane, a tilt direction may be an R-direction, an A-direction, or a C-direction. In addition, if necessary, in a case where the crystal plane of the sapphire substrate is the C-plane, a tilt direction may be an A-direction, an M-direction, or an R-direction. The sapphire substrate may be tilted at a tilt angle θ ranging from 0 degree to 10 degrees with respect to a horizontal plane.

Accordingly, in a case where the M-plane is selected as the crystal plane of the sapphire substrate and the sapphire substrate is titled as above, a semi-polar nitride semiconductor layer grown in a direction perpendicular to a (11-22) plane may be formed on an off-axis of the corresponding crystal plane as illustrated in FIG. 2. In a case where the A-plane is selected as the crystal plane of the sapphire substrate, a semi-polar nitride semiconductor layer grown in a predetermined direction may be formed on an off-axis of the corresponding crystal plane. In a case where the R-plane is selected as the crystal plane of the sapphire substrate, a non-polar nitride semiconductor layer grown in a direction perpendicular to a (11-20) plane may be formed on an off-axis of the corresponding crystal plane. As described above, the C-plane may be selected as the crystal plane of the sapphire substrate, and a predetermined non-polar or semi-polar nitride semiconductor layer may be formed thereon.

The following description will be given on a semiconductor optical device and a manufacturing method thereof. In order to form a non-polar or semi-polar nitride semiconductor layer, the semiconductor optical device employs a sapphire substrate that uses an A-plane, an M-plane, or an R-plane as a crystal plane and is tilted in a predetermined direction as illustrated in FIG. 3. The semiconductor optical device refers to a nitride semiconductor optical device, such as an LED, an LD, a photo detector, or a solar cell. Although an LED will be described as an example of the semiconductor optical device, the invention is not limited thereto. The invention may also be similarly applied to a method for manufacturing other nitride semiconductor optical devices, such as an LD, a photo detector, or a solar cell, by forming a non-polar or semi-polar nitride semiconductor layer on a sapphire substrate, which uses an A-plane, an M-plane, an R-plane, or a C-plane as a crystal plane and is tilted in a predetermined direction. Moreover, the method for manufacturing the semiconductor optical device according to the present invention may also be similarly applied to a method for manufacturing a semiconductor electronic device, such as a general diode or transistor.

FIG. 4 is a cross-sectional view for explaining a structure of a semiconductor optical device 100 according to an embodiment of the present invention.

Referring to FIG. 4, the semiconductor optical device 100 according to the embodiment of the present invention includes a sapphire substrate 110, a template layer 120, and an LED layer 130. In the sapphire substrate 110, a crystal plane (for example, an A-plane, an M-plane, an R-plane, or a C-plane), which enables the growth of a non-polar or semi-polar nitride semiconductor layer, is tilted in a range from 0 degree to 10 degrees. The template layer 120 and the LED layer 130 are formed on the sapphire substrate 110.

The sapphire substrate 110, whose crystal plane (the A-plane, the M-plane, or the R-plane) is tilted in a range from 0 degree to 10 degrees, is prepared. The template layer 120 formed of a non-polar or semi-polar nitride semiconductor layer may be grown on the sapphire substrate 110 through a vacuum deposition process, such as metal organic chemical vapor deposition (MOCVD). The LED layer 130 may be grown on the template layer 120.

The template layer 120 includes a nitride semiconductor layer and an undoped GaN layer. For example, a low-temperature nitride semiconductor layer having an empirical formula of InₓAl_{y}Ga_{1-x-y}N (0≦x≦1, 0≦y≦1, 0≦x+y≦1) may be formed to a thickness of 10 to 20,000 Å at a certain temperature within a temperature range of 400 to 700° C., and a high-temperature undoped GaN layer may be formed on the low-temperature nitride semiconductor layer. The high-temperature undoped GaN layer may be grown at a high temperature, for example, at a certain temperature within a temperature range of 800 to 1,100° C., and may be formed to a thickness of 10 to 20,000 Å. Furthermore, in order to further reduce a crystal defect, such as an area defect and a line defect, on the surface of the GaN layer, a high-temperature nitride semiconductor layer may be further formed between the low-temperature nitride semiconductor layer and the high-temperature undoped GaN layer, which constitute the template layer 120. The high-temperature nitride semiconductor layer may have an empirical formula of InₓAl_{y}Ga_{1-x-y}N (0≦x≦1, 0≦y≦1, 0≦x+y≦1), and may be formed to a thickness of 10 to 20,000 Å at a certain temperature within a temperature range of 700 to 1,100° C.

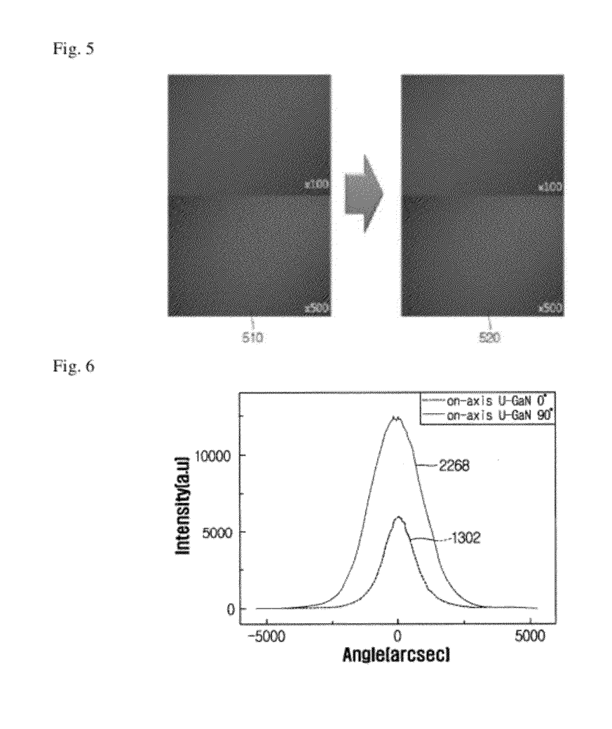

Accordingly, as indicated by reference numeral 510 of FIG. 5, when the polar GaN layer was formed on the sapphire substrate using the C-plane as the crystal plane, the crystal defect existed on the surface of the polar GaN layer and therefore the surface roughness was great. On the contrary, as indicated by reference numeral 520 of FIG. 5, it can be seen that the crystal state of the surface of the undoped GaN layer according to the embodiment of the present invention was excellent because many crystal defects such as the area defect and the line defect were reduced and the surface roughness was decreased.

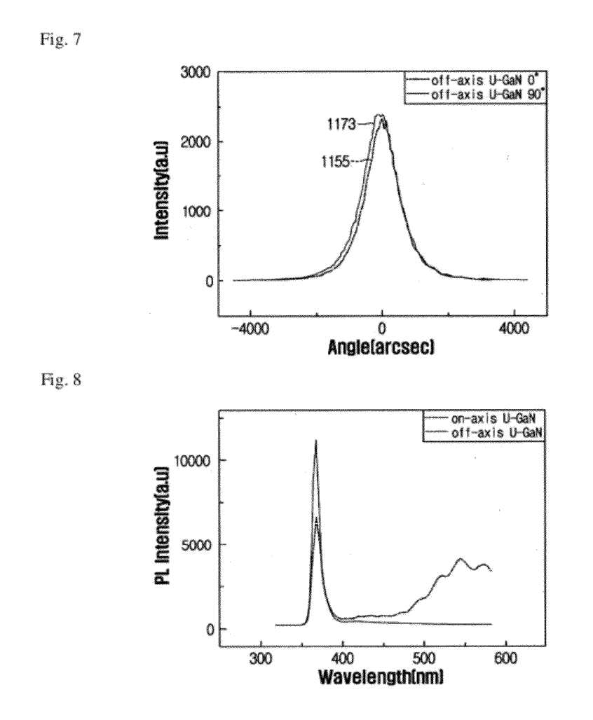

As such, the reduction in the crystal defects leads to a reduction in crystal strain. The uniform non-polar or semi-polar nitride semiconductor layer with reduced crystal defects can also be verified from FIGS. 6 and 7.

As can be seen from FIG. 6, which shows XRD intensity with respect to the surface of the polar GaN layer formed on the sapphire substrate using the C-plane as the crystal plane, a full-width at half maximum (FWHM) value was about 2,268 arcsec in a direction perpendicular to the M-direction (on-axis U-GaN 90°) and was about 1,302 arcsec in a direction parallel to the M-direction (on-axis U-GaN 0°).

On the other hand, as can be seen from FIG. 7, which shows XRD intensity with respect to the surface of the undoped GaN layer according to the embodiment of the present invention, an FWHM value was about 1,173 arcsec in a direction perpendicular to the M-direction (off-axis U-GaN 90°) and was about 1,155 arcsec in a direction parallel to the M-direction (off-axis U-GaN 0°). The result of FIG. 7 was obtained when the R-plane was used as the sapphire crystal plane and was tilted in the M-direction by about 0.2°.

As described above, the FWHM value obtained in the structure of the present invention is much smaller than that obtained in the structure of the related art. This represents that the degree of crystallinity in the structure of the present invention is higher than that in the structure of the related art.

In a case where the template layer 120, in which the crystal defects are remarkably reduced and the degree of crystallinity is improved, is formed and then the semiconductor optical device structure, such as an LED, an LD, a photo detector, or a solar cell, is formed on the template layer 120, it may be possible to suppress a piezoelectric effect occurring in a polar nitride semiconductor layer included in the structure of the related art. Moreover, an electron-hole recombination rate in the optical device may be increased, improving the quantum efficiency thereof. As a result, the brightness of the optical device may be improved.

For example, in a case where the LED layer 130 is formed on the template layer 120, the LED layer 130 may have a structure in which active layers 132 and 133 are disposed between an n-type nitride semiconductor layer 131 and a p-type nitride semiconductor layer 134, as illustrated in FIG. 4.

The n-type nitride semiconductor layer 131 may be formed by growing a GaN layer doped with impurities, such as Si, to a thickness of about 2 micrometers.

The active layers 132 and 133 may include a multi quantum well (MQW) layer 132 and an electron blocking layer (EBL) 133. Specifically, the MQW layer 132 is formed by alternately laminating a GaN barrier layer (about 7.5 nanometers) and an In_{0.15}Ga_{0.85}N well layer (about 2.5 nanometers) several times (for example, five times). The electron blocking layer 133 is formed using an Al_{0.12}Ga_{0.88}N layer (about 20 nanometers).

The InGaN well layer and the GaN barrier layer of the MQW layer 132 may be doped at a Si dopant concentration of about 1×10¹⁹/cm³, and the electron blocking layer 133 may be doped at a Mg dopant concentration of about 5×10¹⁹/cm³. Although the In_{0.15}Ga_{0.85}N well layer has been described as an example of the InGaN well layer, the invention is not limited thereto. Like InₓGa₁₋ₓN (0<x<1), a ratio of In and Ga may be changed. In addition, although the Al_{0.12}Ga_{0.88}N layer has been described as an example of the electron blocking layer 133, the invention is not limited thereto. Like AlₓGa₁₋ₓN (0<x<1), a ratio of Al and Ga may be changed. Furthermore, the InGaN well layer and the GaN barrier layer of the MQW layer 132 may be doped with at least one of O, S, C, Ge, Zn, Cd, and Mg, as well as Si.

The p-type nitride semiconductor layer 134 may be formed by growing a GaN layer doped at an Mg dopant concentration of about 5×10¹⁹/cm³ to a thickness of about 100 nanometers.

Electrodes 141 and 142 for applying voltages may be formed on the n-type nitride semiconductor layer 131 and the p-type nitride semiconductor layer 134, respectively. The completed LED may be mounted on a predetermined package substrate and function as an individual optical device.

As can be seen from FIG. 8, in a case (on-axis U-GaN) where an LED was formed after a polar GaN layer was formed on a sapphire substrate using a C-plane as a crystal plane, PL intensity was low. On the contrary, like in the embodiment of the present invention, in a case (off-axis U-GaN) where an R-plane was used as a sapphire crystal plane and tilted by about 0.2° in an M-direction, it was verified that PL intensity at a corresponding visible light wavelength was high.

As described above, not only the LED layer 130 but also other semiconductor electronic devices or other semiconductor optical device structures, such as an LD, a photo detector, or a solar cell, may be formed on the template layer 120, as illustrated in FIG. 4. A piezoelectric effect may be suppressed at the active layers 132 and 133, and so on. Therefore, the electron-hole recombination rate and the quantum efficiency may be improved, contributing to the performance (e.g., brightness) improvement of the devices.

While the embodiments of the present invention has been described with reference to the specific embodiments, it will be apparent to those skilled in the art that various changes and modifications may be made without departing from the spirit and scope of the invention as defined in the following claims.

1. A method for manufacturing a semiconductor device, the method comprising:
forming a sapphire substrate having a tilted crystal plane; and
forming a template layer on the sapphire substrate, the template layer comprising a nitride semiconductor layer and a GaN layer.

2. A semiconductor device manufactured by the manufacturing method of claim 1.

3. The semiconductor device of claim 2, wherein the crystal plane of the sapphire substrate includes an A-plane, an M-plane, or an R-plane.

4. The semiconductor device of claim 2, wherein the crystal plane of the sapphire substrate is an A-plane, an M-plane, or an R-plane, and is tilted in an A-direction, an M-direction, an R-direction, or a C-direction.

5. The semiconductor device of claim 2, wherein the crystal plane of the sapphire substrate is tilted in a range of 0 to 10 degrees with respect to a horizontal plane.

6. The semiconductor device of claim 2, wherein the nitride semiconductor layer includes an InₓAl_{y}Ga_{1-x-y}N layer (0≦x≦1, 0≦y≦1, 0≦x+y≦1).

7. The semiconductor device of claim 2, wherein the semiconductor device comprises a light emitting diode (LED) including an active layer between an n-type nitride semiconductor layer and a p-type nitride semiconductor layer.

8. The semiconductor device of claim 2, wherein the semiconductor device comprises an optical device including a light emitting diode, a laser diode, a photo detector, or a solar cell, or comprises an electronic device including a transistor.

9. A semiconductor device, comprising:
a sapphire substrate with a tilted crystal plane; and
a template layer disposed on the sapphire substrate, the template layer comprising a nitride semiconductor layer and a GaN layer on the sapphire substrate.

10. The semiconductor device of claim 9, further comprising:
a light emitting diode (LED) layer disposed on the template layer.

11. The semiconductor device of claim 9, wherein the crystal plane of the sapphire substrate includes an A-plane, an M-plane, or an R-plane.

12. The semiconductor device of claim 9, wherein the crystal plane of the sapphire substrate is an A-plane, an M-plane, or an R-plane, and is tilted in an A-direction, an M-direction, an R-direction, or a C-direction.

13. The semiconductor device of claim 9, wherein the crystal plane of the sapphire substrate is tilted in a range of 0 to 10 degrees with respect to a horizontal plane.

14. The semiconductor device of claim 9, wherein the nitride semiconductor layer includes an InₓAl_{y}Ga_{1-x-y}N layer (0≦x≦1, 0≦y≦1, 0≦x+y≦1).

15. The semiconductor device of claim 9, wherein the semiconductor device comprises a light emitting diode (LED) including an active layer between an n-type nitride semiconductor layer and a p-type nitride semiconductor layer.

16. The semiconductor device of claim 9, wherein the semiconductor device comprises an optical device including a light emitting diode, a laser diode, a photo detector, or a solar cell, or comprises an electronic device including a transistor.

17. The semiconductor device of claim 10, wherein the LED layer comprises:
an n-type nitride semiconductor layer disposed on the template layer;
an active layer disposed on the n-type nitride semiconductor layer; and
a p-type nitride semiconductor layer disposed on the active layer.

18. The semiconductor device of claim 17, wherein the active layer comprises:
a multi quantum well (MQW) layer; and
an electron blocking layer (EBL) disposed on the MQW layer.

19. The semiconductor device of claim 18, wherein the MQW layer comprises a GaN barrier layer and an InGaN well layer.
